(19) United States
(12) Patent Application Publication
(10) Pub. No.: US 2024/0330559 A1
(43) Pub. Date: Oct. 3, 2024

(54) METHODS, APPARATUS, AND ARTICLES OF MANUFACTURE TO GROUP DESIGN STAGES IN DESIGN SPACE OPTIMIZATION OF SEMICONDUCTOR DESIGN FOR TOOL AGNOSTIC DESIGN FLOWS

(71) Applicant: Intel Corporation, Santa Clara, CA (US)

(72) Inventors: Raghavendra Vasappanavara, Folsom, CA (US); Srinivasa R Stg, Bangalore (IN); Narendra Nimmagadda, Bangalore (IN); Fadi Aboud, Nazareth (IL)

(21) Appl. No.: 18/194,237

(22) Filed: Mar. 31, 2023

(51) Int. Cl. G06F 30/392

(52) U.S. Cl. CPC G06F 30/392

(57) ABSTRACT

Methods, apparatus, systems, and articles of manufacture are disclosed to group design stages in design space optimization of semiconductor design for tool agnostic design flows. An example apparatus is to parse a file to identify a first design stage and a second design stage of a design flow, the first design stage and the second design stage corresponding to a class of design stages. Additionally, the example apparatus is to generate, based on a dictionary file, a group of operations to perform the first design stage and the second design stage, the dictionary file associated with the first design stage and the second design stage. The example apparatus is also to generate adjusted parameters for experimenting on the class of design stages, the adjusted parameters based on the group of operations. Additionally, the example apparatus is to generate instructions based on the group of operations and the adjusted parameters.

### FIELD OF THE DISCLOSURE

This disclosure relates generally to design optimization and, more particularly, to methods, apparatus, and articles of manufacture to group design stages in design space optimization of semiconductor design for tool agnostic design flows.

### BACKGROUND

Designing modern integrated circuits (ICs) is a complicated process involving many input parameters. For example, designers (e.g., engineers) designing ICs consider which components to include in an IC, how many components to include in the IC, placement of components in the IC, operating modes (e.g., power, performance, cost, clocking, etc.) of each component, routing between components, and design rules, among others. The many input parameters considered in the design of ICs produce a highly dimensional design space of possible combinations of the input parameters.

To navigate design spaces, designers utilize manual design space exploration (DSE) techniques. Manual DSE techniques involve the designer systematically analyzing and removing different combinations of input parameters in a design space until the combinations converge on a satisfactory result. Because manual DSE techniques are labor intensive, tools have been developed to aid in IC design. Such tools may be referred to as structural design recipe search and optimization (S&O) tools. For example, structural design recipe S&O tools utilize artificial intelligence (AI) techniques to automate, at least partially, the search through a design space until convergence on a combination of input parameters that produces a satisfactory result.

### BRIEF DESCRIPTION OF THE DRAWINGS

FIG. 1 is a diagram illustrating example processes utilized by a structural design recipe S&O tool in optimizing an intermediate design stage.

FIG. 2 illustrates an example set of experiments.

FIG. 3 is a block diagram illustrating an example system for automated grouping of design stages of a design flow.

FIG. 4 is a block diagram of the example design flow slicing circuitry of FIG. 3.

FIG. 5 illustrates a portion of the example stack file of FIG. 3.

FIG. 6 illustrates example processes of the structural design recipe search and optimization tool of FIG. 3.

FIG. 7 illustrates dynamic groupings of intermediate design stages.

FIG. 8 illustrates example benefits of design stage groupings.

FIG. 9 is a flowchart representative of example machine-readable instructions and/or example operations that may be executed by example processor circuitry to implement the system of FIG. 3.

FIG. 10 is a block diagram of an example processing platform including processor circuitry structured to execute the example machine-readable instructions and/or the example operations of FIG. 9 to implement the system of FIG. 3.

FIG. 11 is a block diagram of an example implementation of the processor circuitry of FIG. 10.

FIG. 12 is a block diagram of another example implementation of the processor circuitry of FIG. 10.

FIG. 13 is a block diagram of an example software distribution platform (e.g., one or more servers) to distribute software (e.g., software corresponding to the example machine-readable instructions of FIG. 9) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not to scale. As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special-purpose electrical circuits structured to perform specific operation(s) and including one or more semiconductor-based logic devices (e.g., electrical hardware implemented by one or more transistors), and/or (ii) one or more general-purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s). In some examples, Application Specific Integrated Circuitry refers to an ASIC.

### DETAILED DESCRIPTION

Designing modern ICs is complicated due to the large design space that includes multiple combinations of input parameters for the design of an IC. Furthermore, when designing an IC, designers may subdivide the design process (e.g., design flow) into intermediate design stages. To aid in the analysis of input parameters to an intermediate design stage, structural design recipe S&O tools utilize AI techniques to navigate the design space. Generally, structural design recipe S&O tools are designed to analyze a single intermediate design stage of a design flow. For example, structural design recipe S&O tools utilize reinforcement learning (RL) to evaluate multiple combinations of input parameters for an intermediate design stage and select one or more combinations of input parameters to proceed in analysis. The one or more combinations of input parameters may be further tuned by a designer to produce a final combination of input parameters for the intermediate design stage.

FIG. 1 is a diagram 100 illustrating example processes utilized by an example structural design recipe S&O tool 102 in optimizing an intermediate design stage. In the example of FIG. 1, the structural design recipe S&O tool 102 receives an example configuration file 104 and example input parameters 106 for the intermediate design stage. The configuration file 104 may include weights indicating which variables included in the input parameters 106 have a larger impact (e.g., compared to other variables of the input parameters 106) on a target result of the intermediate design stage. The configuration file 104 also indicates a range of values across which to sweep variables of the input parameters 106.

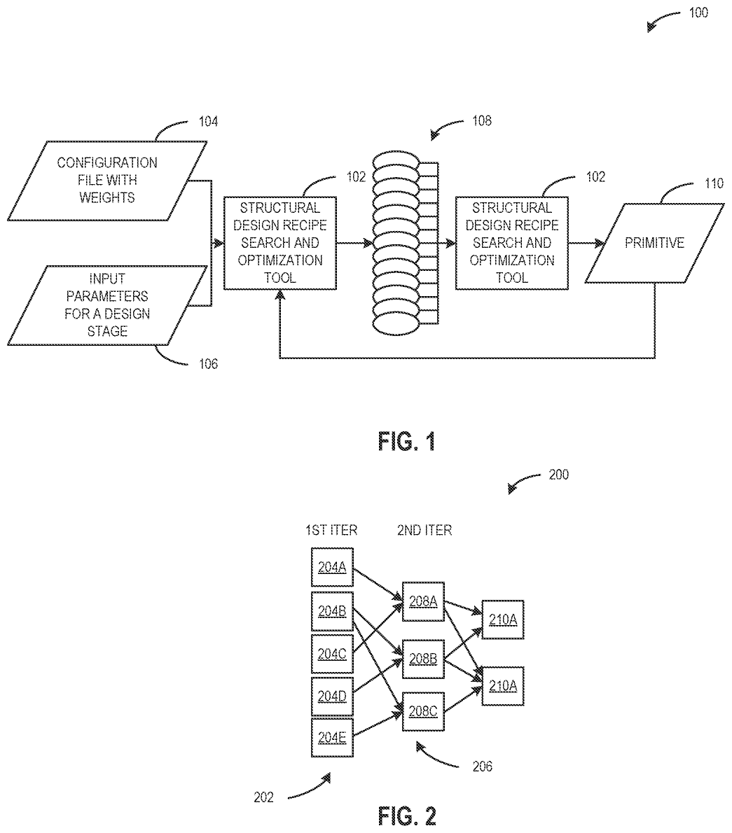

In the illustrated example of FIG. 1, the structural design recipe S&O tool 102 sequences the input parameters 106 into multiple combinations based on the configuration file 104 and generates one or more scripts to simulate an example set of experiments 108 on the multiple combinations of the input parameter 106. The one or more scripts may specify the one or more combinations of the input parameters 106 to be experimented on and one or more ranges across which to sweep one or more variables of the input parameters 106. For example, FIG. 2 illustrates an example set of experiments 200.

The example set of experiments 200 of FIG. 2 includes a first example iteration 202 of experiments that evaluate (actually and/or via simulation) five different example combinations of input parameters 204A-204E (e.g., combination of the input parameters 106) for an intermediate design task. In the illustrated example of FIG. 2, the results of the first iteration 202 of experiments are used to determine which combinations of input parameters (e.g., the input parameters 106) to evaluate in a second example iteration 206 of experiments.

Returning to FIG. 1, the structural design recipe S&O tool 102 classifies the results of the first iteration (e.g., the first iteration 202) of the set of experiments 108 and aggregates one or more of the input parameters 106 into one or more combinations of the input parameters 106 to be tested in a second iteration (e.g., the second iteration 206) of the set of experiments 108. For example, the structural design recipe S&O tool 102 of FIG. 1 samples across the results of the first iteration (e.g., the first iteration 202) of the set of experiments 108 to identify which of the input parameters 106 provide results that are closest to the target result. The structural design recipe S&O tool 102 of FIG. 1 aggregates the identified ones of the input parameters 106 and reformats those input parameters into an example primitive 110 including one or more combinations of the identified ones of the input parameters 106 for subsequent experimentation. Additionally, the structural design recipe S&O tool 102 of FIG. 1 may display (e.g., dashboard) results of the first iteration (e.g., the first iteration 202) of the set of experiments 108 to a user of the structural design recipe S&O tool 102.

Returning to FIG. 2, in the second example iteration 206 of experiments, the structural design recipe S&O tool 102 simulates three different example combinations of input parameters 208A-208C based on the generated primitive (e.g., the primitive 110). In the example of FIG. 2, the results of the second iteration 206 of experiments are used to determine which combinations of input parameters to evaluate further in design space optimization processes. For example, two different example combinations of input parameters 210A, 210B are generated based on the results of the second iteration 206 of experiments and a designer (e.g., an engineer) may conduct further experimentation on the two example combinations of input parameters 210A, 210B. Such further experimentation may provide a result for the intermediate design stage.

While structural design recipe S&O tools are effective tools, the multiple iterations required by structural design recipe S&O tools for each intermediate design stage, as illustrated in FIGS. 1 and 2, is very time consuming and very taxing on the computational infrastructure of an entity designing semiconductors. For example, the numerous experiments simulated for each intermediate design stage require a large amount of computational resources (e.g., processor resources and/or storage resources). Furthermore, the many execution cycles of structural design recipe S&O tools can increase licensing costs paid to vendors of structural design recipe S&O tools. These non-recurring engineering (NRE) costs are increasing per design. For example, significant monetary resources are expended for licensing structural design recipe S&O tools and a significant amount of computational resources are required to execute the structural design recipe S&O tools for each stage in a design flow.

Additionally, because structural design recipe S&O tools are designed to improve (e.g., optimize) intermediate design stages in a design flow, entities designing semiconductors typically create a funneling mechanism to provide the result of a first intermediate design stage to a second intermediate design stage. In examples disclosed herein, the result of a first intermediate design stage may be referred to as a seed and a seed may be utilized as an input to a second intermediate design stage. Furthermore, while a target result achieved by a structural design recipe S&O tool for an intermediate design stage may be satisfactory for the intermediate design stage, the target result may not always result in a satisfactory result for the overall design flow because the entire design space is not evaluated by the structural design recipe S&O tool. For example, utilizing different seeds as the input to an intermediate design stage may result in different results for the intermediate design stage.

Examples disclosed herein reduce design experimentation time by collectively evaluating combinations of intermediate design stages. As such, disclosed methods, apparatus, and articles of manufacture reduce NRE costs, reduce design iterations, and release additional computational resources for other processes. For example, storage resources utilized by, processor resources utilized by, and licensing costs for structural design recipe S&O tools are reduced as two or more intermediate design stages of a design flow are evaluated together. Additionally, by combining intermediate design stages for analysis, examples disclosed herein converge on better results that other structural design recipe S&O tools that evaluate individual intermediate design stages.

Additionally, examples disclosed herein reduce the headcount (e.g., number of employees) to be utilized when developing an IC. Modern ICs include anywhere from 10s of thousands of transistors to 10s of billions of transistors and will continue to increase according to Moore's Law. To design such complex ICs, entities designing ICs divide the workload between multiple designers (e.g., engineers) such that an individual designer is responsible for designing a more manageable number of transistor for a particular logical block (e.g., registers, arithmetic logic units (ALUs), memory, etc.) of an IC. By reducing NRE costs, reducing design iterations, and releasing additional computational resources for other processes, examples disclosed herein allow for designers to work on other designs and/or perform other work thereby improving the efficiency of a workplace.

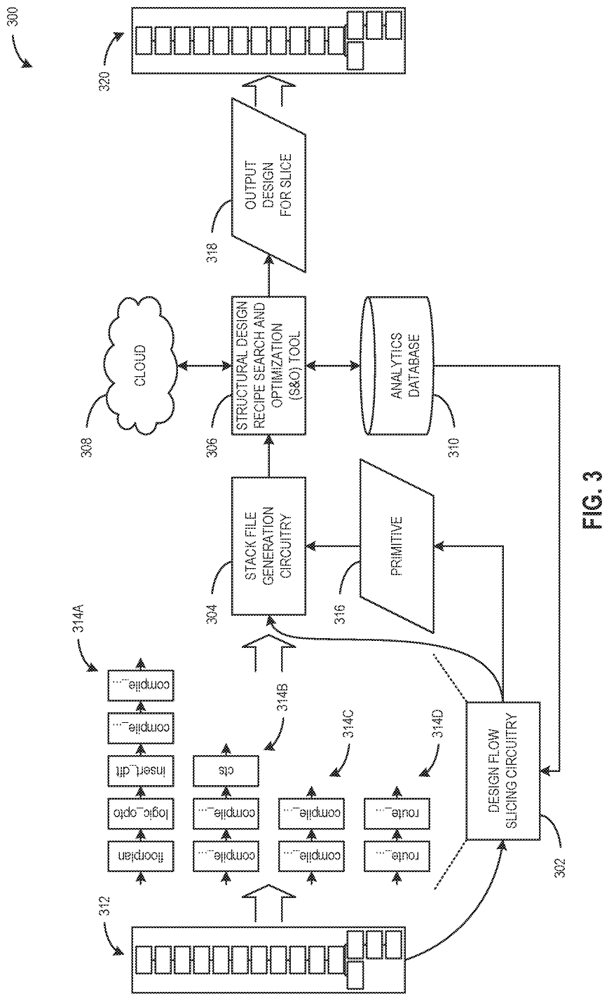

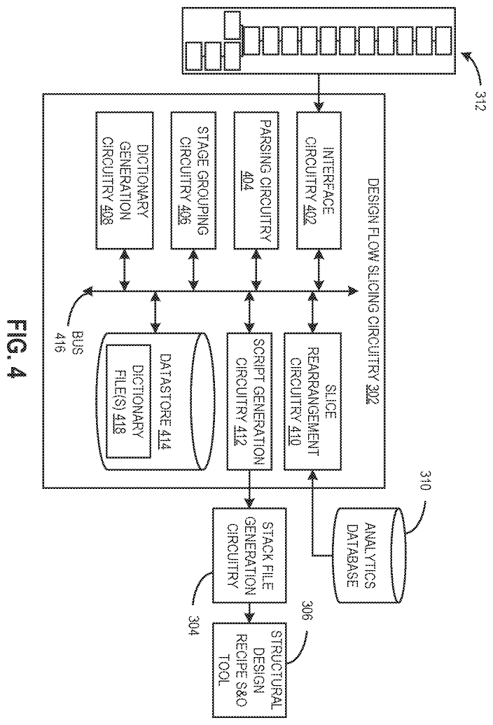

FIG. 3 is a block diagram illustrating an example system 300 for automated grouping of design stages of a design flow. The example system 300 includes example design flow slicing circuitry 302, example stack file generation circuitry 304, an example structural design recipe search and optimization (S&O) tool 306, example cloud computing resources 308, and an example analytics database 310. In the example of FIG. 3, the design flow slicing circuitry 302 is coupled to the stack file generation circuitry 304 and the analytics database 310. The example stack file generation circuitry 304 is coupled to the design flow slicing circuitry 302 and the structural design recipe S&O tool 306. In the example of FIG. 3, the structural design recipe S&O tool 306 is coupled to the stack file generation circuitry 304, the cloud computing resources 308, and the analytics database 310.

In the illustrated example of FIG. 3, the design flow slicing circuitry 302 is implemented by processor circuitry executing and/or instantiating machine-readable instructions. In the example of FIG. 3, the design flow slicing circuitry 302 accesses and/or otherwise receives an example stack file 312 representative of an example design flow. The example design flow includes two or more design stages for the design of an IC. In examples disclosed herein, example design stages include (1) analysis of register transfer level (RTL) model(s) of component(s) of an IC, analysis of unified power format (UPF) data for the IC, and analysis of design settings for the design of the IC; (2) initialization of a floorplan for the IC and initialization of timing constraints for the IC; (3) mapping behavioral model(s) of component(s) of the IC to the RTL model(s), setting power and ground (PG) network(s) for the IC, and inputting physical cell(s) (e.g., abstract representation(s)) for component(s) of the IC; (4) placement of component(s) of the IC and optimization of the placement of the component(s) of the IC; (5) synthesis of clock(s) for the IC, routing of traces for clock signal(s) of the IC, and optimization thereof; and (6) routing of traces for other signal(s) of the IC and optimization thereof.

In the illustrated example of FIG. 3, the design flow slicing circuitry 302 creates one or more groupings of design stages to be experimented on by the structural design recipe S&O tool 306. For example, the design flow slicing circuitry 302 slices the design flow represented by the stack file 312 based on one or more user inputs. In the example of FIG. 3, the design flow slicing circuitry 302 creates a first example design flow slice 314A, a second example design flow slice 314B, a third example design flow slice 314C, and a fourth example design flow slice 314D.

In examples disclosed herein, example user inputs include a class of design stages to group together (e.g., a logical grouping of design stages), application options with which to execute the structural design recipe S&O tool 306, and/or a version of the structural design recipe S&O tool 306 with which to perform the experiments. Additionally, example user inputs include parameters for experimenting on a class of design stages (e.g., a range of values across which to sweep independent variables identified in the parameters). In the example of FIG. 3, the system 300 hosts a user interface through which a user can specify a class of design stages and/or parameters for experimenting on the class of design stages. Based on the class of design stages and the parameters, the design flow slicing circuitry 302 generates one or more scripts to facilitate experimentation on the class of design stages.

In this manner, the design flow slicing circuitry 302 creates stage groupings (e.g., design flow slices) with unique configurations and derives possible permutations that address the combination of design stages by flow configuration (e.g., class of design stages), application option combinations, and/or tool binary (e.g., structural design recipe S&O tool 306 version) combinations thereby optimizing computational resources utilized during experimentation. In the example of FIG. 3, example classes of design stages (e.g., logical groupings of design stages) include (1) compile design stages, (2) clock design stages, (3) route design stages, (4) clock and route design stages, (5) compile and clock design stages, (6) compile, clock, and route design stages, and (7) all design stages.

In the illustrated example of FIG. 3, by logically grouping design stages, the design flow slicing circuitry 302 improves overall design space optimization performed by the structural design recipe S&O tool 306. For example, by generating design stage groupings, the design flow slicing circuitry 302 enables the structural design recipe S&O tool 306 to evaluate a larger portion of the design space for a given IC than other systems that evaluate a single design stage. As such, the design flow slicing circuitry 302 reduces computational resource consumption of the system 300 by combining the analysis of intermediate design stages which reduces experimentation time and reduces the sets of experiments (e.g., three sets of experiments to evaluate two design stages as a group compared to six sets of experiments to evaluate two design stages individually).

In the illustrated example of FIG. 3, the stack file generation circuitry 304 is implemented by processor circuitry executing and/or instantiating machine-readable instructions. In the example of FIG. 3, the stack file generation circuitry 304 generates a stack file to format the group of design stages for processing by the structural design recipe S&O tool 306. For example, the stack file generation circuitry 304 generates a stack file based on one or more scripts generated by the design flow slicing circuitry 302. By generating a stack file for the group of design stages, the stack file generation circuitry 304 facilitates design flow slicing regardless of the vendor of the structural design recipe S&O tool 306. As such, the system 300 is tool agnostic and ensures compliance with the structural design recipe S&O tool 306 regardless of vendor.

In the illustrated example of FIG. 3, the structural design recipe S&O tool 306 is implemented by processor circuitry executing and/or instantiating machine-readable instructions. For example, the structural design recipe S&O tool 306 is implemented by processor circuitry executing software developed by an entity designing an IC and/or developed by a third party. In some examples, the structural design recipe S&O tool 306 may be implemented by one or more instances of software executing on the cloud computing resources 308. For example, the cloud computing resources 308 may be implemented by computational resources at one or more datacenters owned, leased, and/or otherwise operated by by Amazon Web Services®, Microsoft Azure®, Google Cloud®, IBM Cloud®, among others.

In the illustrated example of FIG. 3, the structural design recipe S&O tool 306 sequences the stack file generated by the stack file generation circuitry 304 into multiple combinations of input parameters based on the stack file and simulates an example set of experiments to experiment on the multiple combinations of input parameters. Additionally, the example structural design recipe S&O tool 306 classifies the results of the set of experiments and aggregates one or more independent variables being experimented on that achieve results closest to a target result. Additionally, the example structural design recipe S&O tool 306 aggregates the identified ones of the input parameters and reformats those input parameters into an example primitive 316 including one or more combinations of the identified ones of the input parameters for subsequent experimentation.

In the illustrated example of FIG. 3, the structural design recipe S&O tool 306 displays (e.g., dashboards) results of the set of experiments to a user of the system 300. Additionally, the structural design recipe S&O tool 306 stores (e.g., causes storage of) data in the analytics database 310 for use by the design flow slicing circuitry 302 in generating one or more scripts to experiment on a group of design stages. After completing a set of experiments, the structural design recipe S&O tool 306 generates an example output design 318 for a selected slice (e.g., group of design stages). In the example of FIG. 3, the output design 318 represents one or more combinations of input parameters that achieves a result closest to a target result for a group of design stages. In the example of FIG. 3, the structural design recipe S&O tool 306 outputs the output design 318 for the selected slice to an example design 320 for the IC.

In the illustrated example of FIG. 3, the analytics database 310 records data. For example, the analytics database 310 records data representative of findings discovered during execution of a set of experiments. Such findings include values of key performance indicators (KPIs) for each combination of input parameters, adjustments to the combinations of input parameters that move the KPIs to converge on a target result, among others. The analytics database 310 may be implemented by a volatile memory (e.g., a Synchronous Dynamic Random Access Memory (SDRAM), Dynamic Random Access Memory (DRAM), RAMBUS Dynamic Random Access Memory (RDRAM), etc.) and/or a non-volatile memory (e.g., flash memory). The analytics database 310 may additionally or alternatively be implemented by one or more double data rate (DDR) memories, such as DDR, DDR2, DDR3, DDR4, DDR5, mobile DDR (mDDR), DDR SDRAM, etc.

The analytics database 310 may additionally or alternatively be implemented by one or more mass storage devices such as hard disk drive(s) (HDD(s)), compact disk (CD) drive(s), digital versatile disk (DVD) drive(s), solid-state disk (SSD) drive(s), Secure Digital (SD) card(s), CompactFlash (CF) card(s), etc. While in the illustrated example the analytics database 310 is illustrated as a single database, the analytics database 310 may be implemented by any number and/or type(s) of databases. Furthermore, the data stored in the analytics database 310 may be in any data format such as, for example, binary data, comma delimited data, tab delimited data, structured query language (SQL) structures, etc.

FIG. 4 is a block diagram of the example design flow slicing circuitry 302 of FIG. 3. In the example of FIG. 4, the design flow slicing circuitry 302 includes example interface circuitry 402, example parsing circuitry 404, example stage grouping circuitry 406, example dictionary generation circuitry 408, example slice rearrangement circuitry 410, example script generation circuitry 412, an example datastore 414, and an example bus 416. The example datastore 414 of FIG. 4 includes one or more example dictionary files 418. In the illustrated example of FIG. 4, the interface circuitry 402, the parsing circuitry 404, the stage grouping circuitry 406, the dictionary generation circuitry 408, the slice rearrangement circuitry 410, the script generation circuitry 412, and the datastore 414 are in communication with one(s) of each other via the bus 416. For example, the bus 416 can be implemented by at least one of an Inter-Integrated Circuit (I2C) bus, a Serial Peripheral Interface (SPI) bus, a Peripheral Component Interconnect (PCI) bus, or a Peripheral Component Interconnect Express (PCIe or PCIE) bus. Additionally or alternatively, the bus 416 can be implemented by any other type of computing or electrical bus.

The design flow slicing circuitry 302 of FIG. 4 may be instantiated (e.g., creating an instance of, bring into being for any length of time, materialize, implement, etc.) by processor circuitry such as a central processing unit executing instructions. Additionally or alternatively, the design flow slicing circuitry 302 of FIG. 4 may be instantiated (e.g., creating an instance of, bring into being for any length of time, materialize, implement, etc.) by an ASIC or an FPGA structured to perform operations corresponding to the instructions (e.g., operations corresponding to instructions). It should be understood that some or all of the circuitry of FIG. 4 may, thus, be instantiated at the same or different times. Some or all of the circuitry may be instantiated, for example, in one or more threads executing concurrently on hardware and/or in series on hardware. Moreover, in some examples, some or all of the circuitry of FIG. 4 may be implemented by microprocessor circuitry executing instructions to implement one or more virtual machines and/or containers.

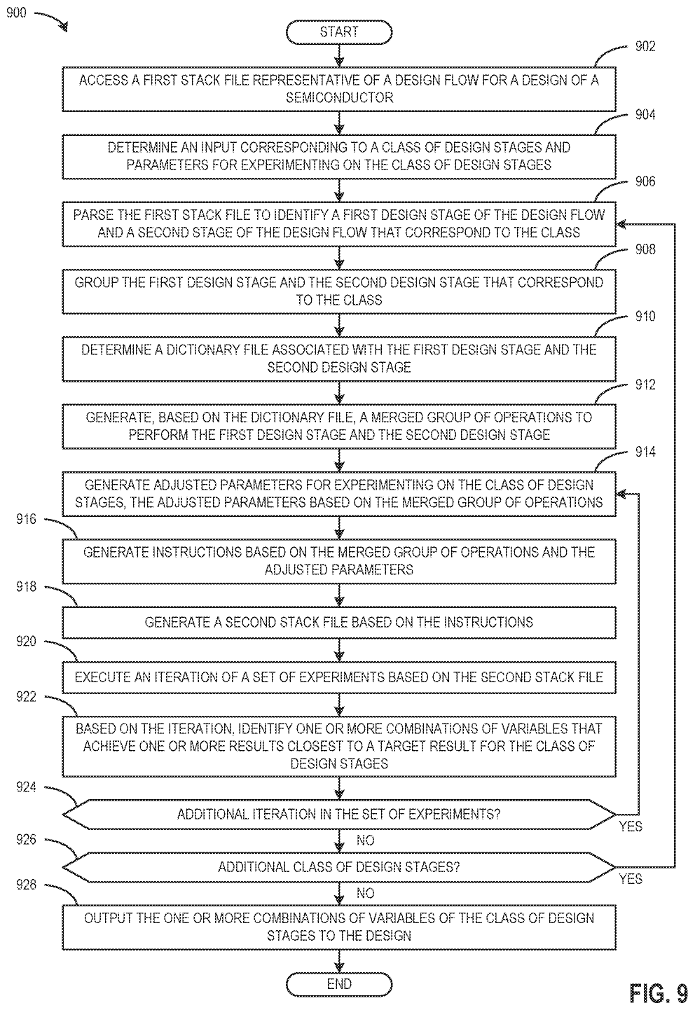

In the illustrated example of FIG. 4, the interface circuitry 402 accesses a stack file representative of a design flow. For example, the interface circuitry 402 accesses the stack file 312 of FIG. 3. The interface circuitry 402 may access a stack file by reading memory and/or storage of a device. In some examples, the interface circuitry 402 receives a stack file via a network. In the example of FIG. 3, the interface circuitry 402 determines an input corresponding to a class of design stages and parameters for experimenting on the class of design stages. For example, the input may be provided by a user (e.g., a user input). In some examples, the interface circuitry 402 is instantiated by processor circuitry executing interfacing instructions and/or configured to perform operations such as those represented by the flowchart of FIG. 9.

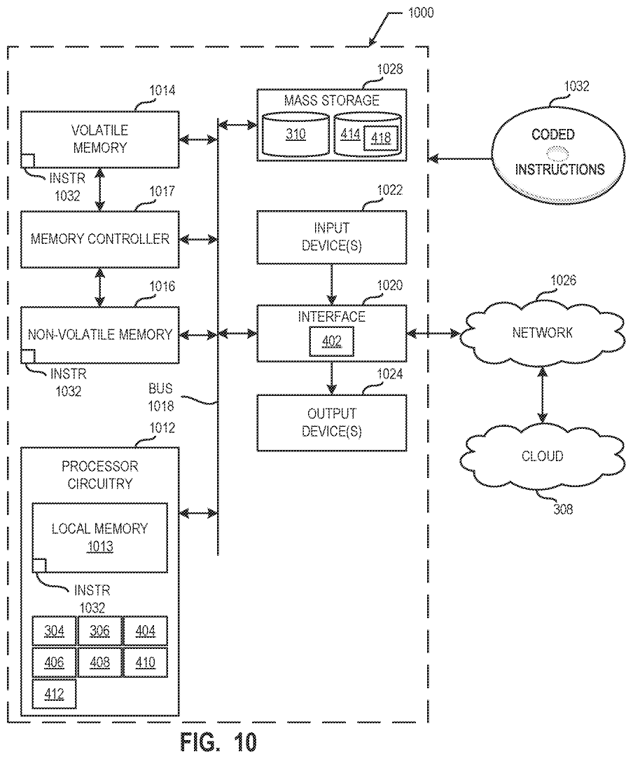

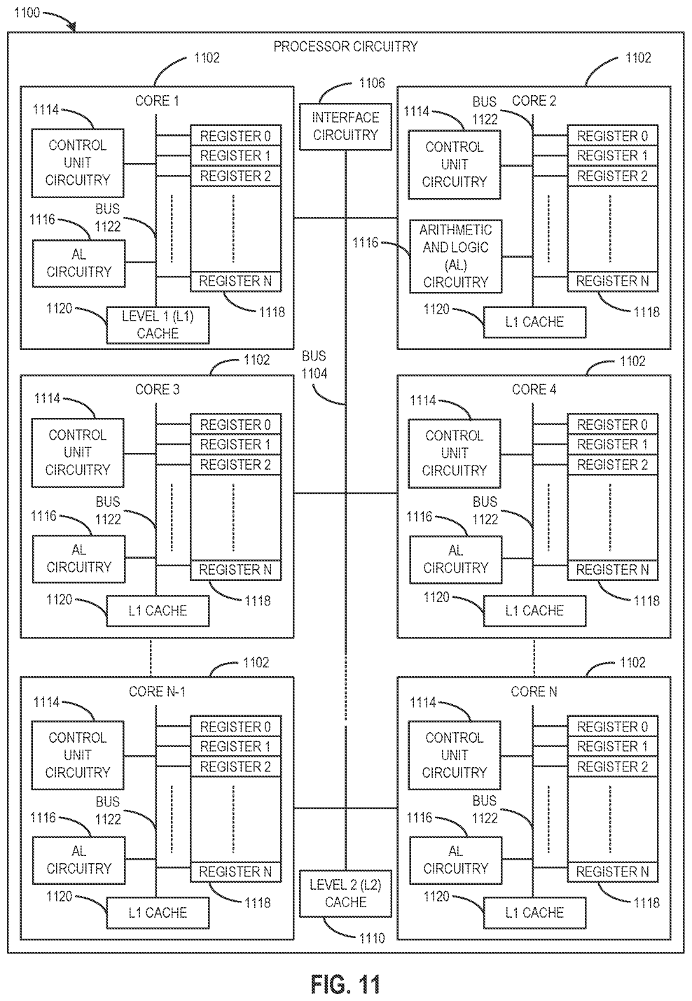

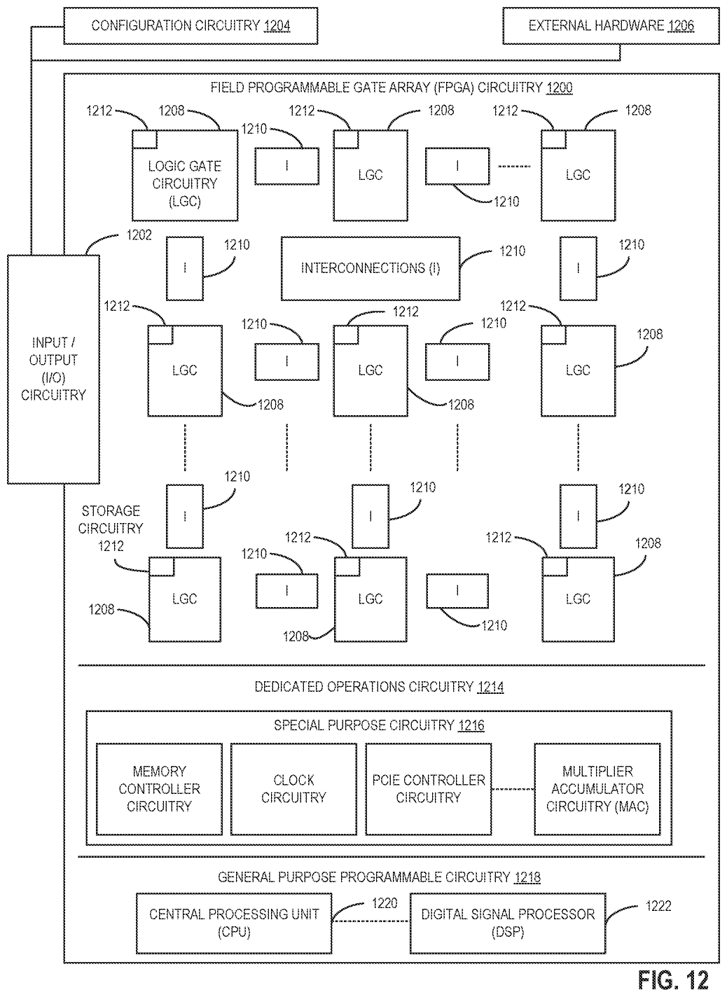

In some examples, the design flow slicing circuitry 302 includes means for accessing. For example, the means for accessing may be implemented by the interface circuitry 402. In some examples, the interface circuitry 402 may be instantiated by processor circuitry such as the example processor circuitry 1012 of FIG. 10. For instance, the interface circuitry 402 may be instantiated by the example microprocessor 1100 of FIG. 11 executing machine-executable instructions such as those implemented by at least blocks 902, 904, 926 of FIG. 9. In some examples, the interface circuitry 402 may be instantiated by hardware logic circuitry, which may be implemented by an ASIC, XPU, or the FPGA circuitry 1200 of FIG. 12 structured to perform operations corresponding to the machine-readable instructions. Additionally or alternatively, the interface circuitry 402 may be instantiated by any other combination of hardware, software, and/or firmware. For example, the interface circuitry 402 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine-readable instructions and/or to perform some or all of the operations corresponding to the machine-readable instructions without executing software or firmware, but other structures are likewise appropriate.

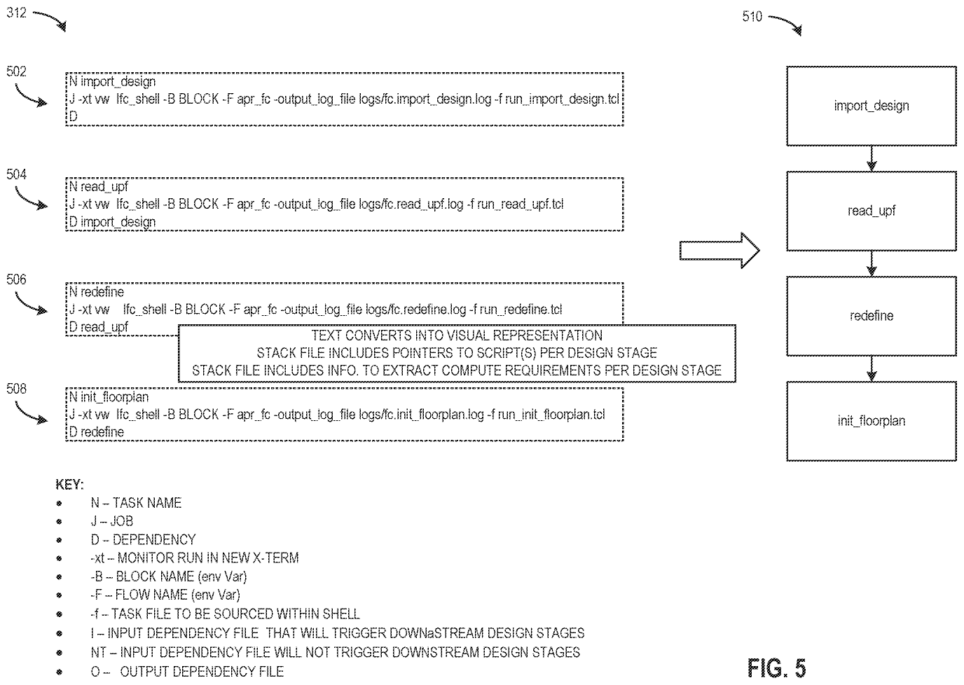

In the illustrated example of FIG. 4, the parsing circuitry 404 parses the stack file (e.g., the stack file 312 of FIG. 3) to identify two or more design stages of the design flow that are related to a class of design stages identified in an input (e.g., a user input). For example, the class of design stages identifies (1) compile design stages, (2) clock design stages, (3) route design stages, (4) clock and route design stages, (5) compile and clock design stages, (6) compile, clock, and route design stages, and (7) all design stages. In the example of FIG. 4, the parsing circuitry 404 identifies design stages related to a specified class of design stages based on the syntax of the stack file (e.g., the stack file 312 of FIG. 3). For example, FIG. 5 illustrates a portion of the example stack file 312 of FIG. 3. In the example of FIG. 5, the portion of the stack file 312 includes a first example design stage 502, a second example design stage 504, a third example design stage 506, and a fourth example design stage 508.

In the illustrated example of FIG. 5, a design stage (e.g., the first design stage 502, the second design stage 504, the third design stage 506, the fourth design stage 508, etc.) can include a name field (identified by the text “N”) for the design stage, a job field (identified by the text “J”) for the design stage, and a dependency field (identified by the text “D”) for the design stage. The job field for a design stage may further specify a variable (identified by the text “-xt”) to be monitored during experimentation on the design stage, a name (identified by the text “-B”) of the design stage, a design flow (identified by the text “-F”) to which the design stage corresponds, a task file (identified by the text “-f”) including one or more scripts to be utilized to implement experimentation on the design stage, an input dependency file of the design stage that will trigger performance of downstream (e.g., later in the design flow) design stages (identified by the text “I”), an input dependency file of the design stage that will not trigger performance of downstream (e.g., later in the design flow) design stages (identified by the text “NT”), and an output dependency file (identified by the text “O”) of the design stage.

For example, the second design stage 504 includes a name field “N read_upf” and a dependency field “D import_design.” In the example of FIG. 5, the job field of the second design stage 504 specifies a variable “-xt vw” to be monitored during experimentation on the second design stage 504 and an input dependency file “Ifc_shell” of the second design stage 504 that will trigger performance of downstream design stages (e.g., the third design stage 506, the fourth design stage 508, etc.). The job field of the second example design stage 504 also specifies a name “-B BLOCK” of the second design stage 504 and a design flow “-F apr_fc-output_log_file logs/fc.read upflog” to which the second design stage 504 corresponds. Additionally, the job field of the second example design stage 504 specifies a task file “-f run_read_upf.tcl” including one or more scripts to be utilized to implement experimentation on the design stage.

In this manner, the task file identifier of the job field of an example design stage operates as a pointer to one or more scripts to implement experimentation on the design stage. The task file may be implemented as a tool command language (TCL) file including importable TCL code and/or an executable TCL script. Additionally, the information included in the stack file 312 allows for the determination of the computational resources required to perform experimentation on a design stage. Furthermore, based on the syntax of the stack file 312, the system 300 can convert the stack file 312 into a visual representation such as an example visual representation 510 of the stack file 312. In some examples, the parsing circuitry 404 is instantiated by processor circuitry executing parsing instructions and/or configured to perform operations such as those represented by the flowchart of FIG. 9.

In some examples, the design flow slicing circuitry 302 includes means for parsing. For example, the means for parsing may be implemented by the parsing circuitry 404. In some examples, the parsing circuitry 404 may be instantiated by processor circuitry such as the example processor circuitry 1012 of FIG. 10. For instance, the parsing circuitry 404 may be instantiated by the example microprocessor 1100 of FIG. 11 executing machine-executable instructions such as those implemented by at least block 906 of FIG. 9. In some examples, the parsing circuitry 404 may be instantiated by hardware logic circuitry, which may be implemented by an ASIC, XPU, or the FPGA circuitry 1200 of FIG. 12 structured to perform operations corresponding to the machine-readable instructions. Additionally or alternatively, the parsing circuitry 404 may be instantiated by any other combination of hardware, software, and/or firmware. For example, the parsing circuitry 404 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine-readable instructions and/or to perform some or all of the operations corresponding to the machine-readable instructions without executing software or firmware, but other structures are likewise appropriate.

Returning to the illustrated example FIG. 4, based on the two or more design stages identified by the parsing circuitry 404, the stage grouping circuitry 406 groups the two or more design stages. For example, the stage grouping circuitry 406 generates an intermediate data structure in the datastore 414 including the text from the stack file (e.g., the stack file 312) corresponding to the two or more identified design stages. In the example of FIG. 4, the intermediate data structure may be overwritten and/or deleted on subsequent operation of the stage grouping circuitry 406. For example, when grouping two or more design stages corresponding to a newly identified class of design stages, the stage grouping circuitry 406 may overwrite an intermediate data structure in the datastore 414 utilized to store design stages related to a previously identified class of design stages. In some examples, the stage grouping circuitry 406 is instantiated by processor circuitry executing stage grouping instructions and/or configured to perform operations such as those represented by the flowchart of FIG. 9.

In some examples, the design flow slicing circuitry 302 includes means for grouping. For example, the means for grouping may be implemented by the stage grouping circuitry 406. In some examples, the stage grouping circuitry 406 may be instantiated by processor circuitry such as the example processor circuitry 1012 of FIG. 10. For instance, the stage grouping circuitry 406 may be instantiated by the example microprocessor 1100 of FIG. 11 executing machine-executable instructions such as those implemented by at least block 908 of FIG. 9. In some examples, the stage grouping circuitry 406 may be instantiated by hardware logic circuitry, which may be implemented by an ASIC, XPU, or the FPGA circuitry 1200 of FIG. 12 structured to perform operations corresponding to the machine-readable instructions. Additionally or alternatively, the stage grouping circuitry 406 may be instantiated by any other combination of hardware, software, and/or firmware. For example, the stage grouping circuitry 406 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine-readable instructions and/or to perform some or all of the operations corresponding to the machine-readable instructions without executing software or firmware, but other structures are likewise appropriate.

In the illustrated example of FIG. 4, the dictionary generation circuitry 408 determines a dictionary file for (e.g., associated with) the two or more design stages of the design flow that are related to the identified class of design stages. For example, for each design stage, the dictionary generation circuitry 408 identifies and extracts one or more variables to be experimented on for the design stage. Additionally, for each design stage, the example dictionary generation circuitry 408 identifies and extracts a sequence of operations to execute to perform the design stage (e.g., design stage content). For example, the dictionary generation circuitry 408 identifies a task file identified for a design stage and extracts the one or more scripts included in the task file.

In the illustrated example of FIG. 4, for each design stage, the dictionary generation circuitry 408 identifies and extracts computational resources required to perform experimentation on the design stage. Additionally, for each design stage, the dictionary generation circuitry 408 parameters for experimenting on the design stage (e.g., a range of values across which to sweep the one or more variables). In the example of FIG. 4, the dictionary generation circuitry 408 stores (e.g., causes storage of) identified and extracted information as the one or more dictionary files 418 in the datastore 414. In some examples, the dictionary generation circuitry 408 is instantiated by processor circuitry executing dictionary generation instructions and/or configured to perform operations such as those represented by the flowchart of FIG. 9.

In some examples, the design flow slicing circuitry 302 includes means for determining. For example, the means for determining may be implemented by the dictionary generation circuitry 408. In some examples, the dictionary generation circuitry 408 may be instantiated by processor circuitry such as the example processor circuitry 1012 of FIG. 10. For instance, the dictionary generation circuitry 408 may be instantiated by the example microprocessor 1100 of FIG. 11 executing machine-executable instructions such as those implemented by at least block 910 of FIG. 9. In some examples, the dictionary generation circuitry 408 may be instantiated by hardware logic circuitry, which may be implemented by an ASIC, XPU, or the FPGA circuitry 1200 of FIG. 12 structured to perform operations corresponding to the machine-readable instructions. Additionally or alternatively, the dictionary generation circuitry 408 may be instantiated by any other combination of hardware, software, and/or firmware. For example, the dictionary generation circuitry 408 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine-readable instructions and/or to perform some or all of the operations corresponding to the machine-readable instructions without executing software or firmware, but other structures are likewise appropriate.

In the illustrated example of FIG. 4, the slice rearrangement circuitry 410 generates a merged group of operations to perform the two or more design stages based on the one or more dictionary files 418. For example, the slice rearrangement circuitry 410 reorders and/or otherwise rearranges the operations included in the one or more scripts identified by the one or more dictionary files 418. For example, the slice rearrangement circuitry 410 reorders and/or otherwise rearranges the operations so that the combined group of design stages appears to the structural design recipe S&O tool 306 as an individual design stage.

In the illustrated example of FIG. 4, the slice rearrangement circuitry 410 generates adjusted parameters for experimenting on the class of design stages. For example, the slice rearrangement circuitry 410 generates the adjusted parameters based on the merged group of operations. In some examples, the slice rearrangement circuitry 410 generates the merged group of operations and the adjusted parameters based on information stored in the analytics database 310 (e.g., findings discovered during execution of a set of experiments). Additionally, in some examples, the slice rearrangement circuitry 410 is instantiated by processor circuitry executing slice rearrangement instructions and/or configured to perform operations such as those represented by the flowchart of FIG. 9.

In some examples, the design flow slicing circuitry 302 includes means for rearranging. For example, the means for rearranging may be implemented by the slice rearrangement circuitry 410. In some examples, the slice rearrangement circuitry 410 may be instantiated by processor circuitry such as the example processor circuitry 1012 of FIG. 10. For instance, the slice rearrangement circuitry 410 may be instantiated by the example microprocessor 1100 of FIG. 11 executing machine-executable instructions such as those implemented by at least blocks 912 and 914 of FIG. 9. In some examples, the slice rearrangement circuitry 410 may be instantiated by hardware logic circuitry, which may be implemented by an ASIC, XPU, or the FPGA circuitry 1200 of FIG. 12 structured to perform operations corresponding to the machine-readable instructions. Additionally or alternatively, the slice rearrangement circuitry 410 may be instantiated by any other combination of hardware, software, and/or firmware. For example, the slice rearrangement circuitry 410 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine-readable instructions and/or to perform some or all of the operations corresponding to the machine-readable instructions without executing software or firmware, but other structures are likewise appropriate.

In the illustrated example of FIG. 4, the script generation circuitry 412 generates one or more scripts to facilitate experimentation on the class of design stages based on the merged group of operations and the adjusted parameters for experimenting on the class of design stages. For example, the script generation circuitry 412 generates a task file including the one or more scripts. In the example of FIG. 4, the script generation circuitry 412 generates a TCL file including importable TCL code and/or one or more executable TCL scripts. Additionally, the script generation circuitry 412 outputs (e.g., transmits, causes transmission via the interface circuitry 402, etc.) the one or more scripts to the stack file generation circuitry 304 so that the stack file generation circuitry 304 can generate a stack file for the class of design stages.

In some examples, the script generation circuitry 412 stores (e.g., causes storage) of the one or more scripts in memory and/or storage of the system 300. Additionally or alternatively, the script generation circuitry 412 outputs file names and/or file locations of the one or more scripts to the stack file generation circuitry 304. In some examples, the script generation circuitry 412 is instantiated by processor circuitry executing script generation instructions and/or configured to perform operations such as those represented by the flowchart of FIG. 9.

In some examples, the design flow slicing circuitry 302 includes means for generating. For example, the means for generating may be implemented by the script generation circuitry 412. In some examples, the script generation circuitry 412 may be instantiated by processor circuitry such as the example processor circuitry 1012 of FIG. 10. For instance, the script generation circuitry 412 may be instantiated by the example microprocessor 1100 of FIG. 11 executing machine-executable instructions such as those implemented by at least block 916 of FIG. 9. In some examples, the script generation circuitry 412 may be instantiated by hardware logic circuitry, which may be implemented by an ASIC, XPU, or the FPGA circuitry 1200 of FIG. 12 structured to perform operations corresponding to the machine-readable instructions. Additionally or alternatively, the script generation circuitry 412 may be instantiated by any other combination of hardware, software, and/or firmware. For example, the script generation circuitry 412 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine-readable instructions and/or to perform some or all of the operations corresponding to the machine-readable instructions without executing software or firmware, but other structures are likewise appropriate.

In the illustrated example of FIG. 4, after generation of the one or more scripts, the stack file generation circuitry 304 generates a stack file based on the one or more scripts. For example, the stack file generation circuitry 304 generates the stack file similarly to the stack file illustrated in FIG. 5. In some examples, the stack file generation circuitry 304 is instantiated by processor circuitry executing stack file generation instructions and/or configured to perform operations such as those represented by the flowchart of FIG. 9.

In some examples, the design flow slicing circuitry 302 includes means for generating. For example, the means for determining may be implemented by the stack file generation circuitry 304. In some examples, the stack file generation circuitry 304 may be instantiated by processor circuitry such as the example processor circuitry 1012 of FIG. 10. For instance, the stack file generation circuitry 304 may be instantiated by the example microprocessor 1100 of FIG. 11 executing machine-executable instructions such as those implemented by at least block 918 of FIG. 9. In some examples, the stack file generation circuitry 304 may be instantiated by hardware logic circuitry, which may be implemented by an ASIC, XPU, or the FPGA circuitry 1200 of FIG. 12 structured to perform operations corresponding to the machine-readable instructions. Additionally or alternatively, the stack file generation circuitry 304 may be instantiated by any other combination of hardware, software, and/or firmware. For example, the stack file generation circuitry 304 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine-readable instructions and/or to perform some or all of the operations corresponding to the machine-readable instructions without executing software or firmware, but other structures are likewise appropriate.

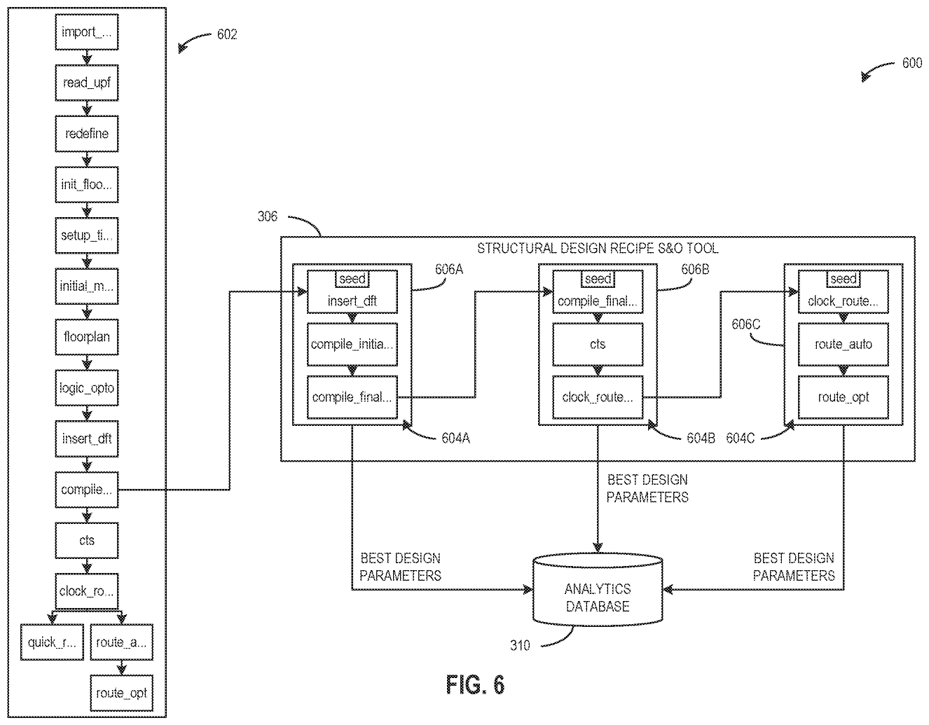

In the illustrated example of FIG. 4, after generation of a stack file by the stack file generation circuitry 304, the structural design recipe S&O tool 306 executes a set of experiments based on the stack file. Based on the set of experiments, the structural design recipe S&O tool 306 identifies one or more combinations of variables that achieve one or more results closest to a target result for the class of design stages. The structural design recipe S&O tool 306 may execute subsequent iterations of the set of experiments to identify the one or more best (e.g., closest to the target result) combinations of variables for the class of design stages. After determining the one or more best combinations, the structural design recipe S&O tool 306 outputs the one or more best combinations to the design for an IC (e.g., the design 320 of FIG. 3). For example, FIG. 6 illustrates example processes 600 of the structural design recipe S&O tool 306 of FIG. 3.

In the illustrated example of FIG. 6, an example stack file 602 is sliced into a first example design flow slice 604A, a second example design flow slice 604B, and a third example design flow slice 604C by the design flow slicing circuitry 302. In the example of FIG. 6, the structural design recipe S&O tool 306 executes a first set of experiments on a first example stack file 606A generated by the stack file generation circuitry 304. The first example stack file 606A corresponds to the first design flow slice 604A. In the example of FIG. 6, the structural design recipe S&O tool 306 stores (e.g., causes storage of) the best parameter combinations for the first design flow slice 604A in the analytics database 310.

In the illustrated example of FIG. 6, the structural design recipe S&O tool 306 executes a second set of experiments on a second example stack file 606B generated by the stack file generation circuitry 304. The second example stack file 606B corresponds to the second design flow slice 604B. In the example of FIG. 6, the best parameter combination for the first design flow slice 604A is utilized as the seed for the second design flow slice 604B. In the example of FIG. 6, the structural design recipe S&O tool 306 executes a third set of experiments on a third example stack file 606C generated by the stack file generation circuitry 304. The third example stack file 606C corresponds to the third design flow slice 604C. In the example of FIG. 6, the best parameter combination for the second design flow slice 604B is utilized as the seed for the third design flow slice 604C. Additionally, in the example of FIG. 6, the structural design recipe S&O tool 306 stores (e.g., causes storage of) the best parameter combinations for the second design flow slice 604B and the third design flow slice 604C in the analytics database 310. In some examples, the structural design recipe S&O tool 306 is instantiated by processor circuitry executing structural design recipe search and optimization instructions and/or configured to perform operations such as those represented by the flowchart of FIG. 9.

In some examples, the design flow slicing circuitry 302 includes means for optimizing. For example, the means for optimizing may be implemented by the structural design recipe S&O tool 306. In some examples, the structural design recipe S&O tool 306 may be instantiated by processor circuitry such as the example processor circuitry 1012 of FIG. 10. For instance, the structural design recipe S&O tool 306 may be instantiated by the example microprocessor 1100 of FIG. 11 executing machine-executable instructions such as those implemented by at least blocks 920, 922, 924, and 928 of FIG. 9. In some examples, the structural design recipe S&O tool 306 may be instantiated by hardware logic circuitry, which may be implemented by an ASIC, XPU, or the FPGA circuitry 1200 of FIG. 12 structured to perform operations corresponding to the machine-readable instructions. Additionally or alternatively, the structural design recipe S&O tool 306 may be instantiated by any other combination of hardware, software, and/or firmware. For example, the structural design recipe S&O tool 306 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine-readable instructions and/or to perform some or all of the operations corresponding to the machine-readable instructions without executing software or firmware, but other structures are likewise appropriate.

In the illustrated example of FIG. 4, the datastore 414 records data. For example, the datastore 414 records data representative of the one or more dictionary files 418 and/or one or more intermediate data structures to store groups of design stages. The datastore 414 may be implemented by a volatile memory (e.g., a SDRAM, DRAM, RDRAM, etc.) and/or a non-volatile memory (e.g., flash memory). The datastore 414 may additionally or alternatively be implemented by one or more DDR memories, such as DDR, DDR2, DDR3, DDR4, DDR5, mDDR, DDR SDRAM, etc.

The datastore 414 may additionally or alternatively be implemented by one or more mass storage devices such as HDD(s), CD drive(s), DVD drive(s), SSD drive(s), SD card(s), CF card(s), etc. While in the illustrated example the datastore 414 is illustrated as a single database, the datastore 414 may be implemented by any number and/or type(s) of databases. Furthermore, the data stored in the datastore 414 may be in any data format such as, for example, binary data, comma delimited data, tab delimited data, SQL structures, etc.

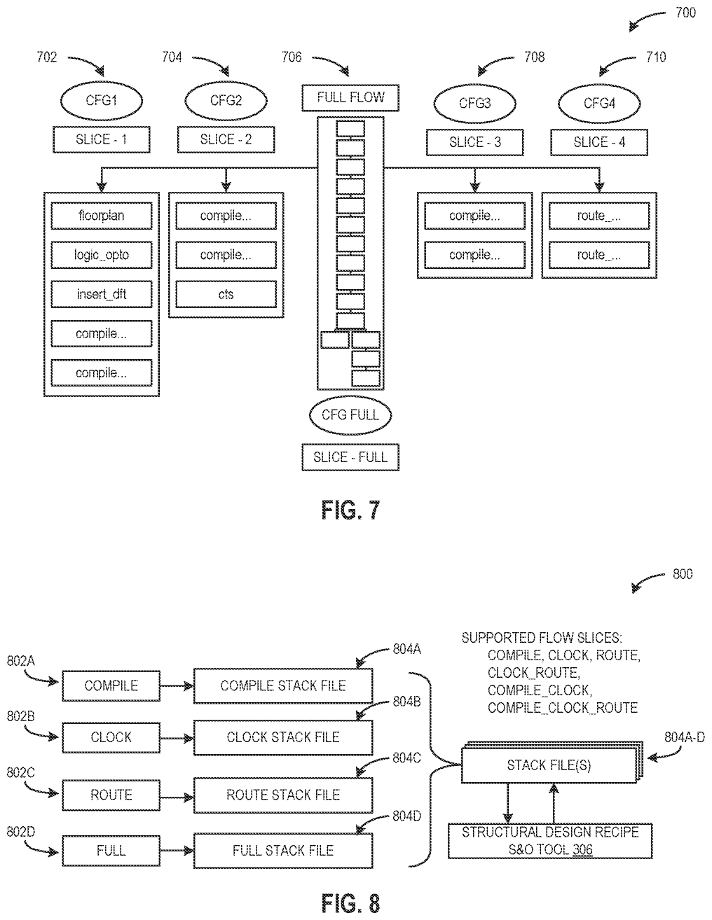

FIG. 7 illustrates dynamic groupings 700 of intermediate design stages. In the example of FIG. 7, the selection of a grouping of design stages to experiment on is user controlled. In additional or alternative examples, processor circuitry (e.g., processor circuitry executing a machine learning model) selects which grouping design stages to experiment on with the structural design recipe S&O tool 306. In the example of FIG. 7, the design flow slicing circuitry 302 logically groups design stages (e.g., groups placement design stages, groups clock design stages, groups route design stages, etc.) to improve the overall application of structural design recipe S&O tools. As such, structural design recipe S&O tools are applied in the socketed mode (e.g., per design stage grouping) as opposed to the linear mode (e.g., per design stage). In this manner (e.g., by merging individual design stages into a group of design stages), the design flow slicing circuitry 302 facilitates evaluation of a group of design stages together which reduces the processor resources utilized for, storage resources utilized for, and total turn-around time for design space optimization experiments. In the example of FIG. 7, a user may select between a first example design stage grouping 702, a second example design stage grouping 704, a third example design stage grouping 706, a fourth example design stage grouping 708, and a fifth example design stage grouping 710 based on requirements of the user's design.

FIG. 8 illustrates example benefits of design stage groupings. The example of FIG. 8 illustrates four example design stage groupings. For example, FIG. 8 illustrates a first example design stage grouping 802A, a second example design stage grouping 802B, a third example design stage grouping 802C, and a fourth example design stage grouping 802D. In the example of FIG. 8, the first design stage grouping 802A groups design stages related to compilation. The second example design stage grouping 802B groups design stages related to clocking. In the example of FIG. 8, the third design stage grouping 802C groups design stages related to routing. The fourth example design stage grouping 802D groups all design stages of a design flow.

In the illustrated example of FIG. 8, each design stage grouping is compiled into a respective stack file which may then be processed by the structural design recipe S&O tool 306. For example, the stack file generation circuitry 304 compiles the first design stage grouping 802A into a first example stack file 804A. Additionally, the stack file generation circuitry 304 compiles the second design stage grouping 802B into a second example stack file 804B. In the example of FIG. 8, the stack file generation circuitry 304 compiles the third design stage grouping 802C into a third example stack file 804C. Additionally, the stack file generation circuitry 304 compiles the fourth design stage grouping 802D into a fourth example stack file 804D.

In the illustrated example of FIG. 8, the structural design recipe S&O tool 306 processes the stack files 804A-804D. For example, when executing the first stack file 804A, the structural design recipe S&O tool 306 tunes and/or controls design parameter combinations to converge the design towards a target result. In some examples, the structural design recipe S&O tool 306 performs multiple iterations of experimentation to tune the design parameter combinations for design stage groupings included in the stack files 804A-804D.

While an example manner of implementing the system 300 of FIG. 3 is illustrated in FIG. 3, one or more of the elements, processes, and/or devices illustrated in FIG. 3 may be combined, divided, re-arranged, omitted, eliminated, and/or implemented in any other way. Additionally, while an example manner of implementing the design flow slicing circuitry 302 of FIG. 3 is illustrated in FIG. 4, one or more of the elements, processes, and/or devices illustrated in FIG. 4 may be combined, divided, re-arranged, omitted, eliminated, and/or implemented in any other way. Further, the example interface circuitry 402, the example parsing circuitry 404, the example stage grouping circuitry 406, the example dictionary generation circuitry 408, the example slice rearrangement circuitry 410, the example script generation circuitry 412, the example datastore 414, and/or, more generally, the example design flow slicing circuitry 302, and/or the example stack file generation circuitry 304, the example structural design recipe S&O tool 306, the example cloud computing resources 308, the example analytics database 310, and/or, more generally, the example system 300 of FIG. 3, may be implemented by hardware alone or by hardware in combination with software and/or firmware. Thus, for example, any of the example interface circuitry 402, the example parsing circuitry 404, the example stage grouping circuitry 406, the example dictionary generation circuitry 408, the example slice rearrangement circuitry 410, the example script generation circuitry 412, the example datastore 414, and/or, more generally, the example design flow slicing circuitry 302, and/or the example stack file generation circuitry 304, the example structural design recipe S&O tool 306, the example cloud computing resources 308, the example analytics database 310, and/or, more generally, the example system 300 of FIG. 3, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example system 300 of FIG. 3 and/or the design flow slicing circuitry 302 of FIG. 4 may include one or more elements, processes, and/or devices in addition to, or instead of, those illustrated in FIGS. 3 and/or 4, and/or may include more than one of any or all of the illustrated elements, processes and devices.

A flowchart representative of example machine-readable instructions, which may be executed to configure processor circuitry (e.g., the instructions cause processor circuitry) to implement the system 300 of FIG. 3, is shown in FIG. 9. The machine-readable instructions may be one or more executable programs or portion(s) of an executable program for execution by processor circuitry, such as the processor circuitry 1012 shown in the example processor platform 1000 discussed below in connection with FIG. 10 and/or the example processor circuitry discussed below in connection with FIGS. 11 and/or 12. The program may be embodied in software stored on one or more non-transitory computer-readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine-readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer-readable storage media may include one or more mediums located in one or more hardware devices. Further, although the example program is described with reference to the flowchart illustrated in FIG. 9, many other methods of implementing the example system 300 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU, an XPU, etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine-readable instructions described herein may be stored in one or more of a compressed format, an encrypted format, a fragmented format, a compiled format, an executable format, a packaged format, etc. Machine-readable instructions as described herein may be stored as data or a data structure (e.g., as portions of instructions, code, representations of code, etc.) that may be utilized to create, manufacture, and/or produce machine-executable instructions. For example, the machine-readable instructions may be fragmented and stored on one or more storage devices and/or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine-readable instructions may be stored in multiple parts, which are individually compressed, encrypted, and/or stored on separate computing devices, wherein the parts when decrypted, decompressed, and/or combined form a set of machine-executable instructions that implement one or more operations that may together form a program such as that described herein.

In another example, the machine-readable instructions may be stored in a state in which they may be read by processor circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions and/or the corresponding program(s) can be executed in whole or in part. Thus, machine-readable media, as used herein, may include machine-readable instructions and/or program(s) regardless of the particular format or state of the machine-readable instructions and/or program(s) when stored or otherwise at rest or in transit.

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 9 may be implemented using executable instructions (e.g., computer and/or machine-readable instructions) stored on one or more non-transitory computer and/or machine-readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer-readable medium, non-transitory computer-readable storage medium, non-transitory machine-readable medium, and non-transitory machine-readable storage medium are expressly defined to include any type of computer-readable storage device and/or storage disk and to exclude propagating signals and to exclude transmission media. As used herein, the terms “computer-readable storage device” and “machine-readable storage device” are defined to include any physical (mechanical and/or electrical) structure to store information, but to exclude propagating signals and to exclude transmission media. Examples of computer-readable storage devices and machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer-readable instructions, machine-readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 9 is a flowchart representative of example machine-readable instructions and/or example operations 900 that may be executed and/or instantiated by example processor circuitry to implement the system 300 of FIG. 3. The machine-readable instructions and/or the operations 900 of FIG. 9 begin at block 902, at which the interface circuitry 402 accesses a first stack file representative of a design flow for a design of a semiconductor. At block 904, the interface circuitry 402 determines an input corresponding to a class of design stages and parameters for experimenting on the class of design stages. For example, the interface circuitry 402 accesses a user input specifying a class of design stages and parameters for experimenting on the class of design stages.

In the illustrated example of FIG. 9, at block 906, the parsing circuitry 404 parses the first stack file to identify two or more design stages of the design flow that correspond to the class of design stages. For example, the parsing circuitry 404 parses the first stack file to identify a first design stage and a second design stage. At block 908, the stage grouping circuitry 406 groups the two or more design stages corresponding to the class of design stages. For example, at block 908, the stage grouping circuitry 406 generates an intermediate data structure in the datastore 414 including text from the first stack file that corresponds to the first design stage and the second design stage. At block 910, the dictionary generation circuitry 408 determines a dictionary file (e.g., the one or more dictionary files 418 of FIG. 4) associated with the two or more design stages. For example, the dictionary generation circuitry 408 determines a dictionary file associated with the first design stage and the second design stage.

In the illustrated example of FIG. 9, at block 910, the dictionary generation circuitry 408 identifies one or more variables to be experimented on for the two or more design stages. For example, the dictionary generation circuitry 408 identifies a first variable of the first design stage on which to experiment and a second variable of the second design stage on which to experiment. Additionally, at block 910, the dictionary generation circuitry 408 identifies two or more operations (e.g., script(s) in task file(s)) to execute to perform the two or more design stages. For example, the dictionary generation circuitry 408 identifies a first operation of the first design stage and a second operation of the second design stage.

In the illustrated example of FIG. 9, at block 910, the dictionary generation circuitry 408 additionally identifies computational resources required to perform experimentation on the two or more design stages. For example, the dictionary generation circuitry 408 identifies first computational resource requirements to perform experimentation on the first design stage and second computational resource requirements to perform experimentation on the second design stage. Additionally, at block 910, the dictionary generation circuitry 408 identifies parameters for experimenting on the two or more design stages. For example, the dictionary generation circuitry 408 identifies first parameters for experimenting on the first design stage and second parameters for experimenting on the second design stage.

In the illustrated example of FIG. 9, at block 912, the slice rearrangement circuitry 410 generates, based on the dictionary file determined for the two or more design stages, a merged group of operations to perform the two or more design stages. For example, at block 912, the slice rearrangement circuitry 410 reorders and/or otherwise rearranges the operations included in the one or more scripts identified in the dictionary file associated with the two or more design stages. At block 914, the slice rearrangement circuitry 410 generates adjusted parameters for experimenting on the class of design stages. For example, based on the merged group of operations, the slice rearrangement circuitry 410 generates the adjusted parameters for experimenting on the class of design stages.

In the illustrated example of FIG. 9, at block 916, the script generation circuitry 412 generates instructions (e.g., one or more scripts) based on the merged group of operations and the adjusted parameters. For example, based on the merged group of operations and the adjusted parameters, the script generation circuitry 412 generates one or more TCL files including importable TCL code and/or one or more executable TCL scripts. At block 918, the stack file generation circuitry 304 generates a second stack file based on the instructions. As described above, by combining two or more design stages of a design flow, examples disclosed herein enable convergence on a better result than analysis of individual design stages. Additionally, combining two or more design stages reduces the processor resources utilized for, storage resources utilized for, and licensing costs for structural design recipe S&O tools and infrastructural support in terms of executing inferences of structural design recipe S&O tools, aggregating results of experiments, and dashboarding (e.g., formatting structural design recipe S&O tool data into a graphical user interface) of the same.

In the illustrated example of FIG. 9, at block 920, the structural design recipe S&O tool 306 executes an iteration of a set of experiments based on the second stack file. At block 922, based on the iteration, the structural design recipe S&O tool 306 identifies one or more combinations of variables that achieve one or more results closest to a target result for the class of design stages. For example, during a first iteration of the set of experiments, the structural design recipe S&O tool 306 identifies one or more first combinations of variables that achieves one or more first results closer to the target result than other one or more combinations of variables experimented on during the first iteration. In a subsequent iteration, the structural design recipe S&O tool 306 identifies one or more second combinations of variables that achieves one or more second results closer to the target result than the one or more first combinations of variables and other one or more combinations of variables experimented on during the subsequent iteration. As such, by completing the set of experiments, the structural design recipe S&O tool 306 identifies the one or more combinations of variables that achieve the one or more results closest to the target result. In the example of FIG. 9, at block 924, the structural design recipe S&O tool 306 determines whether there is an additional iteration in the set of experiments.

In the illustrated example of FIG. 9, in response to (e.g., based on) the structural design recipe S&O tool 306 determining that there is an additional iteration in the set of experiments (block 924: YES), the machine-readable instructions and/or the operations 900 return to block 914. In response to (e.g., based on) the structural design recipe S&O tool 306 determining that there is not an additional iteration in the set of experiments (block 924: NO), the machine-readable instructions and/or the operations 900 proceed to block 926. At block 926, the interface circuitry 402 determines whether there is an additional class of design stages to be grouped.

In the illustrated example of FIG. 9, in response to (e.g., based on) the interface circuitry 402 determining that the there is an additional class of design stages to be grouped (block 926: YES), the machine-readable instructions and/or the operations 900 return to block 906. In response to (e.g., based on) the interface circuitry 402 determining that there is not an additional class of design stages to be grouped (block 926: NO), the machine-readable instructions and/or the operations 900 proceed to block 928. At block 928, the structural design recipe S&O tool 306 outputs the one or more combinations of variables to the design of the semiconductor. For example, the structural design recipe S&O tool 306 outputs the one or more combinations of variables that achieve one or more results closest to a target result for the class of design stages.

FIG. 10 is a block diagram of an example processor platform 1000 structured to execute and/or instantiate the machine-readable instructions and/or the operations 900 of FIG. 9 to implement the system 300 of FIG. 3. The processor platform 1000 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing device.

The processor platform 1000 of the illustrated example includes processor circuitry 1012. The processor circuitry 1012 of the illustrated example is hardware. For example, the processor circuitry 1012 can be implemented by one or more integrated circuits, logic circuits, FPGAs, microprocessors, CPUs, GPUs, DSPs, and/or microcontrollers from any desired family or manufacturer. The processor circuitry 1012 may be implemented by one or more semiconductor based (e.g., silicon based) devices. In this example, the processor circuitry 1012 implements the example stack file generation circuitry 304, the example structural design recipe S&O tool 306, the example parsing circuitry 404, the example stage grouping circuitry 406, the example dictionary generation circuitry 408, the example slice rearrangement circuitry 410, and the example script generation circuitry 412.

The processor circuitry 1012 of the illustrated example includes a local memory 1013 (e.g., a cache, registers, etc.). The processor circuitry 1012 of the illustrated example is in communication with a main memory including a volatile memory 1014 and a non-volatile memory 1016 by a bus 1018. The volatile memory 1014 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1016 may be implemented by flash memory and/or any other desired type of memory device. Access to the main memory 1014, 1016 of the illustrated example is controlled by a memory controller 1017.

The processor platform 1000 of the illustrated example also includes interface circuitry 1020. The interface circuitry 1020 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1022 are connected to the interface circuitry 1020. The input device(s) 1022 permit(s) a user to enter data and/or commands into the processor circuitry 1012. The input device(s) 1022 can be implemented by, for example, an audio sensor, a microphone, a camera (still or video), a keyboard, a button, a mouse, a touchscreen, a track-pad, a trackball, an isopoint device, and/or a voice recognition system.

One or more output devices 1024 are also connected to the interface circuitry 1020 of the illustrated example. The output device(s) 1024 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1020 of the illustrated example, thus, typically includes a graphics driver card, a graphics driver chip, and/or graphics processor circuitry such as a GPU.

The interface circuitry 1020 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1026. The communication can be by, for example, an Ethernet connection, a digital subscriber line (DSL) connection, a telephone line connection, a coaxial cable system, a satellite system, a line-of-site wireless system, a cellular telephone system, an optical connection, etc. In this example, the interface circuitry 1020 implements the example interface circuitry 402. In the example of FIG. 9, the interface circuitry 1020 facilitates communication with the cloud computing resources 308 via the network 1026.

The processor platform 1000 of the illustrated example also includes one or more mass storage devices 1028 to store software and/or data. Examples of such mass storage devices 1028 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives. In this example, the one or more mass storage devices 1028 implements the example analytics database 310 and the example datastore 414. In some examples, the datastore 414 stores the one or more dictionary files 418.

The machine-readable instructions 1032, which may be implemented by the machine-readable instructions of FIG. 9, may be stored in the mass storage device 1028, in the volatile memory 1014, in the non-volatile memory 1016, and/or on a removable non-transitory computer-readable storage medium such as a CD or DVD.

FIG. 11 is a block diagram of an example implementation of the processor circuitry 1012 of FIG. 10. In this example, the processor circuitry 1012 of FIG. 10 is implemented by a microprocessor 1100. For example, the microprocessor 1100 may be a general-purpose microprocessor (e.g., general-purpose microprocessor circuitry). The microprocessor 1100 executes some or all of the machine-readable instructions of the flowchart of FIG. 9 to effectively instantiate the circuitry of FIGS. 3 and/or 4 as logic circuits to perform the operations corresponding to those machine-readable instructions. In some such examples, the circuitry of FIGS. 3 and/or 4 is instantiated by the hardware circuits of the microprocessor 1100 in combination with the instructions. For example, the microprocessor 1100 may be implemented by multi-core hardware circuitry such as a CPU, a DSP, a GPU, an XPU, etc. Although it may include any number of example cores 1102 (e.g., 1 core), the microprocessor 1100 of this example is a multi-core semiconductor device including N cores. The cores 1102 of the microprocessor 1100 may operate independently or may cooperate to execute machine-readable instructions. For example, machine code corresponding to a firmware program, an embedded software program, or a software program may be executed by one of the cores 1102 or may be executed by multiple ones of the cores 1102 at the same or different times. In some examples, the machine code corresponding to the firmware program, the embedded software program, or the software program is split into threads and executed in parallel by two or more of the cores 1102. The software program may correspond to a portion or all of the machine-readable instructions and/or operations represented by the flowchart of FIG. 9.

The cores 1102 may communicate by a first example bus 1104. In some examples, the first bus 1104 may be implemented by a communication bus to effectuate communication associated with one(s) of the cores 1102. For example, the first bus 1104 may be implemented by at least one of an Inter-Integrated Circuit (I2C) bus, a Serial Peripheral Interface (SPI) bus, a PCI bus, or a PCIe bus. Additionally or alternatively, the first bus 1104 may be implemented by any other type of computing or electrical bus. The cores 1102 may obtain data, instructions, and/or signals from one or more external devices by example interface circuitry 1106. The cores 1102 may output data, instructions, and/or signals to the one or more external devices by the interface circuitry 1106. Although the cores 1102 of this example include example local memory 1120 (e.g., Level 1 (L1) cache that may be split into an L1 data cache and an L1 instruction cache), the microprocessor 1100 also includes example shared memory 1110 that may be shared by the cores (e.g., Level 2 (L2 cache)) for high-speed access to data and/or instructions. Data and/or instructions may be transferred (e.g., shared) by writing to and/or reading from the shared memory 1110. The local memory 1120 of each of the cores 1102 and the shared memory 1110 may be part of a hierarchy of storage devices including multiple levels of cache memory and the main memory (e.g., the main memory 1014, 1016 of FIG. 10). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1102 may be referred to as a CPU, DSP, GPU, etc., or any other type of hardware circuitry. Each core 1102 includes control unit circuitry 1114, arithmetic and logic (AL) circuitry 1116 (sometimes referred to as an ALU), a plurality of registers 1118, the local memory 1120, and a second example bus 1122. Other structures may be present. For example, each core 1102 may include vector unit circuitry, single instruction multiple data (SIMD) unit circuitry, load/store unit (LSU) circuitry, branch/jump unit circuitry, floating-point unit (FPU) circuitry, etc. The control unit circuitry 1114 (e.g., control circuitry) includes semiconductor-based circuits structured to control data movement (e.g., coordinate data movement) within the corresponding core 1102. The AL circuitry 1116 includes semiconductor-based circuits structured to perform one or more mathematic and/or logic operations on the data within the corresponding core 1102. The AL circuitry 1116 of some examples performs integer-based operations. In other examples, the AL circuitry 1116 also performs floating point operations. In yet other examples, the AL circuitry 1116 may include first AL circuitry that performs integer-based operations and second AL circuitry that performs floating point operations. In some examples, the AL circuitry 1116 may be referred to as an Arithmetic Logic Unit (ALU) and/or arithmetic and logic circuitry. The registers 1118 are semiconductor-based structures to store data and/or instructions such as results of one or more of the operations performed by the AL circuitry 1116 of the corresponding core 1102. For example, the registers 1118 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1118 may be arranged in a bank as shown in FIG. 11. Alternatively, the registers 1118 may be organized in any other arrangement, format, or structure including distributed throughout the core 1102 to shorten access time. The second bus 1122 may be implemented by at least one of an I2C bus, a SPI bus, a PCI bus, or a PCIe bus.

Each core 1102 and/or, more generally, the microprocessor 1100 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1100 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general-purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

FIG. 12 is a block diagram of another example implementation of the processor circuitry 1012 of FIG. 10. In this example, the processor circuitry 1012 is implemented by FPGA circuitry 1200. For example, the FPGA circuitry 1200 may be implemented by an FPGA. The FPGA circuitry 1200 can be used, for example, to perform operations that could otherwise be performed by the example microprocessor 1100 of FIG. 11 executing corresponding machine-readable instructions. However, once configured, the FPGA circuitry 1200 instantiates the machine-readable instructions in hardware and, thus, can often execute the operations faster than they could be performed by a general-purpose microprocessor executing the corresponding software.

More specifically, in contrast to the microprocessor 1100 of FIG. 11 described above (which is a general-purpose device that may be programmed to execute some or all of the machine-readable instructions represented by the flowchart of FIG. 9 but whose interconnections and logic circuitry are fixed once fabricated), the FPGA circuitry 1200 of the example of FIG. 12 includes interconnections and logic circuitry that may be configured and/or interconnected in different ways after fabrication to instantiate, for example, some or all of the machine-readable instructions represented by the flowchart of FIG. 9. In particular, the FPGA circuitry 1200 may be thought of as an array of logic gates, interconnections, and switches. The switches can be programmed to change how the logic gates are interconnected by the interconnections, effectively forming one or more dedicated logic circuits (unless and until the FPGA circuitry 1200 is reprogrammed). The configured logic circuits enable the logic gates to cooperate in different ways to perform different operations on data received by input circuitry. Those operations may correspond to some or all of the software represented by the flowchart of FIG. 9. As such, the FPGA circuitry 1200 may be structured to effectively instantiate some or all of the machine-readable instructions of the flowchart of FIG. 9 as dedicated logic circuits to perform the operations corresponding to those software instructions in a dedicated manner analogous to an ASIC. Therefore, the FPGA circuitry 1200 may perform the operations corresponding to the some or all of the machine-readable instructions of FIG. 9 faster than the general-purpose microprocessor can execute the same.

In the example of FIG. 12, the FPGA circuitry 1200 is structured to be programmed (and/or reprogrammed one or more times) by an end user by a hardware description language (HDL) such as Verilog. The FPGA circuitry 1200 of FIG. 12, includes example input/output (I/O) circuitry 1202 to obtain and/or output data to/from example configuration circuitry 1204 and/or external hardware 1206. For example, the configuration circuitry 1204 may be implemented by interface circuitry that may obtain machine-readable instructions to configure the FPGA circuitry 1200, or portion(s) thereof. In some such examples, the configuration circuitry 1204 may obtain the machine-readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 1206 may be implemented by external hardware circuitry. For example, the external hardware 1206 may be implemented by the microprocessor 1100 of FIG. 11. The FPGA circuitry 1200 also includes an array of example logic gate circuitry 1208, a plurality of example configurable interconnections 1210, and example storage circuitry 1212. The logic gate circuitry 1208 and the configurable interconnections 1210 are configurable to instantiate one or more operations that may correspond to at least some of the machine-readable instructions of FIG. 9 and/or other desired operations. The logic gate circuitry 1208 shown in FIG. 12 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1208 to enable configuration of the electrical structures and/or the logic gates to form circuits to perform desired operations. The logic gate circuitry 1208 may include other electrical structures such as look-up tables (LUTs), registers (e.g., flip-flops or latches), multiplexers, etc.

The configurable interconnections 1210 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1208 to program desired logic circuits.

The storage circuitry 1212 of the illustrated example is structured to store result(s) of the one or more of the operations performed by corresponding logic gates. The storage circuitry 1212 may be implemented by registers or the like. In the illustrated example, the storage circuitry 1212 is distributed amongst the logic gate circuitry 1208 to facilitate access and increase execution speed.

The example FPGA circuitry 1200 of FIG. 12 also includes example Dedicated Operations Circuitry 1214. In this example, the Dedicated Operations Circuitry 1214 includes special-purpose circuitry 1216 that may be invoked to implement commonly used functions to avoid the need to program those functions in the field. Examples of such special-purpose circuitry 1216 include memory (e.g., DRAM) controller circuitry, PCIe controller circuitry, clock circuitry, transceiver circuitry, memory, and multiplier-accumulator circuitry. Other types of special-purpose circuitry may be present. In some examples, the FPGA circuitry 1200 may also include example general-purpose programmable circuitry 1218 such as an example CPU 1220 and/or an example DSP 1222. Other general-purpose programmable circuitry 1218 may additionally or alternatively be present such as a GPU, an XPU, etc., that can be programmed to perform other operations.

Although FIGS. 11 and 12 illustrate two example implementations of the processor circuitry 1012 of FIG. 10, many other approaches are contemplated. For example, as mentioned above, modern FPGA circuitry may include an on-board CPU, such as one or more of the example CPU 1220 of FIG. 12. Therefore, the processor circuitry 1012 of FIG. 10 may additionally be implemented by combining the example microprocessor 1100 of FIG. 11 and the example FPGA circuitry 1200 of FIG. 12. In some such hybrid examples, a first portion of the machine-readable instructions represented by the flowchart of FIG. 9 may be executed by one or more of the cores 1102 of FIG. 11, a second portion of the machine-readable instructions represented by the flowchart of FIG. 9 may be executed by the FPGA circuitry 1200 of FIG. 12, and/or a third portion of the machine-readable instructions represented by the flowchart of FIG. 9 may be executed by an ASIC. It should be understood that some or all of the circuitry of FIGS. 3 and/or 4 may, thus, be instantiated at the same or different times. Some or all of the circuitry may be instantiated, for example, in one or more threads executing concurrently and/or in series. Moreover, in some examples, some or all of the circuitry of FIGS. 3 and/or 4 may be implemented within one or more virtual machines and/or containers executing on the microprocessor.

In some examples, the processor circuitry 1012 of FIG. 10 may be in one or more packages. For example, the microprocessor 1100 of FIG. 11 and/or the FPGA circuitry 1200 of FIG. 12 may be in one or more packages. In some examples, an XPU may be implemented by the processor circuitry 1012 of FIG. 10, which may be in one or more packages. For example, the XPU may include a CPU in one package, a DSP in another package, a GPU in yet another package, and an FPGA in still yet another package.

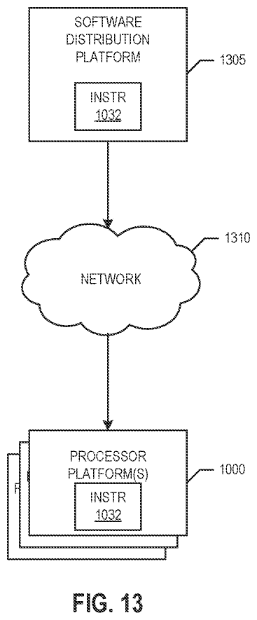

A block diagram illustrating an example software distribution platform 1305 to distribute software such as the example machine-readable instructions 1032 of FIG. 10 to hardware devices owned and/or operated by third parties is illustrated in FIG. 13. The example software distribution platform 1305 may be implemented by any computer server, data facility, cloud service, etc., capable of storing and transmitting software to other computing devices. The third parties may be customers of the entity owning and/or operating the software distribution platform 1305. For example, the entity that owns and/or operates the software distribution platform 1305 may be a developer, a seller, and/or a licensor of software such as the example machine-readable instructions 1032 of FIG. 10. The third parties may be consumers, users, retailers, OEMs, etc., who purchase and/or license the software for use and/or re-sale and/or sub-licensing. In the illustrated example, the software distribution platform 1305 includes one or more servers and one or more storage devices. The storage devices store the machine-readable instructions 1032, which may correspond to the example machine-readable instructions and/or the example operations 900 of FIG. 9, as described above. The one or more servers of the example software distribution platform 1305 are in communication with an example network 1310, which may correspond to any one or more of the Internet and/or any of the example networks (e.g., the network 1026) described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine-readable instructions 1032 from the software distribution platform 1305. For example, the software, which may correspond to the example machine-readable instructions 1032 of FIG. 10, may be downloaded to the example processor platform 1000, which is to execute the machine-readable instructions 1032 to implement the system 300. In some examples, one or more servers of the software distribution platform 1305 periodically offer, transmit, and/or force updates to the software (e.g., the example machine-readable instructions 1032 of FIG. 10) to ensure improvements, patches, updates, etc., are distributed and applied to the software at the end user devices.

From the foregoing, it will be appreciated that example systems, methods, apparatus, and articles of manufacture have been disclosed that group design stages in design space optimization of semiconductor design for tool agnostic design flows. Examples disclosed herein improve semiconductor design. For example, disclosed systems, methods, apparatus, and articles of manufacture reduce design experimentation time by collectively evaluating design stage combinations (e.g., slices). As such, examples disclosed herein allow IC designers to select which slice of a design flow to optimize (e.g., improve) based on the design recovery opportunities for (e.g., opportunities to improve) the design of the IC.

Additionally, examples disclosed herein ensure that the overall design space optimization search is tool agnostic and ensure vendor compliance in the overall design space optimization search. For example, disclosed examples allow vendor recommender systems to operate in sync with reference design flows. Disclosed systems, methods, apparatus, and articles of manufacture improve the efficiency of using a computing device by reducing storage resources utilized by, licensing costs for, and processor resources utilized by structural design recipe S&O tools. Additionally, examples disclosed herein reduce total NRE cost associated with the overall design space optimization search and reduce design iterations in developing future IC designs. Disclosed systems, methods, apparatus, and articles of manufacture are accordingly directed to one or more improvement(s) in the operation of a machine such as a computer or other electronic and/or mechanical device.

Example methods, apparatus, systems, and articles of manufacture to group design stages in design space optimization of semiconductor design for tool agnostic design flows are disclosed herein. Further examples and combinations thereof include the following:

Example 1 includes an apparatus to group design stages in design space optimization of semiconductor design, the apparatus comprising interface circuitry, first instructions, and processor circuitry to at least one of instantiate or execute the first instructions to parse a file to identify a first design stage of a design flow and a second design stage of the design flow, the first design stage and the second design stage corresponding to a class of design stages, generate, based on a dictionary file, a group of operations to perform the first design stage and the second design stage, the dictionary file associated with the first design stage and the second design stage, generate adjusted parameters for experimenting on the class of design stages, the adjusted parameters based on the group of operations, and generate second instructions based on the group of operations and the adjusted parameters.

Example 2 includes the apparatus of example 1, wherein the processor circuitry is to determine the dictionary file associated with the first design stage and the second design stage.

Example 3 includes the apparatus of example 2, wherein to determine the dictionary file, the processor circuitry is to identify (a) a first variable of the first design stage on which to experiment and (b) a second variable of the second design stage on which to experiment.

Example 4 includes the apparatus of any of examples 2 or 3, wherein to determine the dictionary file, the processor circuitry is to identify (a) a first operation of the first design stage and (b) a second operation of the second design stage.

Example 5 includes the apparatus of example 4, wherein to generate the group of operations, the processor circuitry is to adjust (a) the first operation of the first design stage and (b) the second operation of the second design stage.

Example 6 includes the apparatus of any of examples 2, 3, 4, or 5, wherein to determine the dictionary file, the processor circuitry is to identify (a) first parameters for experimenting on the first design stage and (b) second parameters for experimenting on the second design stage.

Example 7 includes the apparatus of example 6, wherein to generate the adjusted parameters for experimenting on the class of design stages, the processor circuitry is to adjust (a) the first parameters of the first design stage and (b) the second parameters of the second design stage based on the group of operations.

Example 8 includes a non-transitory machine-readable storage medium comprising first instructions that, when executed, cause processor circuitry to at least parse a file to identify a first design stage of a design flow and a second design stage of the design flow, the first design stage and the second design stage corresponding to a class of design stages, generate, based on a dictionary file, a group of operations to perform the first design stage and the second design stage, the dictionary file associated with the first design stage and the second design stage, generate adjusted parameters for experimenting on the class of design stages, the adjusted parameters based on the group of operations, and generate second instructions based on the group of operations and the adjusted parameters.

Example 9 includes the non-transitory machine-readable storage medium of example 8, wherein the first instructions cause the processor circuitry to determine the dictionary file associated with the first design stage and the second design stage.

Example 10 includes the non-transitory machine-readable storage medium of example 9, wherein to determine the dictionary file, the first instructions cause the processor circuitry to identify (a) a first variable of the first design stage on which to experiment and (b) a second variable of the second design stage on which to experiment.

Example 11 includes the non-transitory machine-readable storage medium of any of examples 9 or 10, wherein to determine the dictionary file, the first instructions cause the processor circuitry to identify (a) a first operation of the first design stage and (b) a second operation of the second design stage.

Example 12 includes the non-transitory machine-readable storage medium of example 11, wherein to generate the group of operations, the first instructions cause the processor circuitry to adjust (a) the first operation of the first design stage and (b) the second operation of the second design stage.

Example 13 includes the non-transitory machine-readable storage medium of any of examples 9, 10, 11, or 12, wherein to determine the dictionary file, the first instructions cause the processor circuitry to identify (a) first parameters for experimenting on the first design stage and (b) second parameters for experimenting on the second design stage.

Example 14 includes the non-transitory machine-readable storage medium of example 13, wherein to generate the adjusted parameters for experimenting on the class of design stages, the first instructions cause the processor circuitry to adjust (a) the first parameters of the first design stage and (b) the second parameters of the second design stage based on the group of operations.

Example 15 includes a method to group design stages in design space optimization of semiconductor design, the method comprising parsing a file to identify a first design stage of a design flow and a second design stage of the design flow, the first design stage and the second design stage corresponding to a class of design stages, based on a dictionary file, generating, by executing a first instruction with processor circuitry, a group of operations to perform the first design stage and the second design stage, the dictionary file associated with the first design stage and the second design stage, generating, by executing a first instruction with the processor circuitry, adjusted parameters for experimenting on the class of design stages, the adjusted parameters based on the group of operations, and generating, by executing a first instruction with the processor circuitry, second instructions based on the group of operations and the adjusted parameters.

Example 16 includes the method of example 15, further including determining the dictionary file associated with the first design stage and the second design stage.

Example 17 includes the method of example 16, wherein determining the dictionary file includes identifying (a) a first variable of the first design stage on which to experiment and (b) a second variable of the second design stage on which to experiment.

Example 18 includes the method of any of examples 16 or 17, wherein determining the dictionary file includes identifying (a) a first operation of the first design stage and (b) a second operation of the second design stage.

Example 19 includes the method of example 18, wherein generating the group of operations includes adjusting (a) the first operation of the first design stage and (b) the second operation of the second design stage.

Example 20 includes the method of example 16, 17, 18, or 19, wherein determining the dictionary file includes identifying (a) first parameters for experimenting on the first design stage and (b) second parameters for experimenting on the second design stage.

Example 21 includes the method of example 20, wherein generating the adjusted parameters for experimenting on the class of design stages includes adjusting (a) the first parameters of the first design stage and (b) the second parameters of the second design stage based on the group of operations.

Example 22 includes an apparatus to group design stages in design space optimization of semiconductor design, the apparatus comprising means for parsing a file to identify a first design stage of a design flow and a second design stage of the design flow, the first design stage and the second design stage corresponding to a class of design stages, means for rearranging the first design stage and the second design stage to generate, based on a dictionary file, a group of operations to perform the first design stage and the second design stage, the dictionary file associated with the first design stage and the second design stage, and generate adjusted parameters for experimenting on the class of design stages, the adjusted parameters based on the group of operations, and means for generating instructions based on the group of operations and the adjusted parameters.

Example 23 includes the apparatus of example 22, further including means for determining the dictionary file associated with the first design stage and the second design stage.

Example 24 includes the apparatus of example 23, wherein to determine the dictionary file, the means for determining is to identify (a) a first variable of the first design stage on which to experiment and (b) a second variable of the second design stage on which to experiment.

Example 25 includes the apparatus of any of examples 23 or 24, wherein to determine the dictionary file, the means for determining is to identify (a) a first operation of the first design stage and (b) a second operation of the second design stage.

Example 26 includes the apparatus of example 25, wherein to generate the group of operations, the means for rearranging the first design stage and the second design stage is to adjust (a) the first operation of the first design stage and (b) the second operation of the second design stage.

Example 27 includes the apparatus of any of examples 23, 24, 25, or 26, wherein to determine the dictionary file, the means for determining is to identify (a) first parameters for experimenting on the first design stage and (b) second parameters for experimenting on the second design stage.

Example 28 includes the apparatus of example 27, wherein to generate the adjusted parameters for experimenting on the class of design stages, the means for rearranging the first design stage and the second design stage is to adjust (a) the first parameters of the first design stage and (b) the second parameters of the second design stage based on the group of operations.

Example 29 includes an apparatus to group design stages in design space optimization of semiconductor design, the apparatus comprising interface circuitry to access a file representative of a design flow, and processor circuitry including one or more of at least one of a central processor unit (CPU), a graphics processor unit (GPU), or a digital signal processor (DSP), the at least one of the CPU, the GPU, or the DSP having control circuitry to control data movement within the processor circuitry, arithmetic and logic circuitry to perform one or more first operations corresponding to instructions, and one or more registers to store a first result of the one or more first operations, the instructions in the apparatus, a Field Programmable Gate Array (FPGA), the FPGA including first logic gate circuitry, a plurality of configurable interconnections, and storage circuitry, the first logic gate circuitry and the plurality of the configurable interconnections to perform one or more second operations, the storage circuitry to store a second result of the one or more second operations, or Application Specific Integrated Circuitry (ASIC) including second logic gate circuitry to perform one or more third operations, the processor circuitry to perform at least one of the first operations, the second operations, or the third operations to instantiate parsing circuitry to parse the file to identify a first design stage of the design flow and a second design stage of the design flow, the first design stage and the second design stage corresponding to a class of design stages, slice rearrangement circuitry to generate, based on a dictionary file, a group of operations to perform the first design stage and the second design stage, the dictionary file associated with the first design stage and the second design stage, and generate adjusted parameters for experimenting on the class of design stages, the adjusted parameters based on the group of operations, and script generation circuitry to generate instructions based on the group of operations and the adjusted parameters.

Example 30 includes the apparatus of example 29, further including dictionary generation circuitry to determine the dictionary file associated with the first design stage and the second design stage.

Example 31 includes the apparatus of example 30, wherein to determine the dictionary file, the dictionary generation circuitry is to identify (a) a first variable of the first design stage on which to experiment and (b) a second variable of the second design stage on which to experiment.

Example 32 includes the apparatus of any of examples 30 or 31, wherein to determine the dictionary file, the dictionary generation circuitry is to identify (a) a fourth operation of the first design stage and (b) a fifth operation of the second design stage.

Example 33 includes the apparatus of example 32, wherein to generate the group of operations, the slice rearrangement circuitry is to adjust (a) the fourth operation of the first design stage and (b) the fifth operation of the second design stage.

Example 34 includes the apparatus of any of examples 30, 31, 32, or 33, wherein to determine the dictionary file, the dictionary generation circuitry is to identify (a) first parameters for experimenting on the first design stage and (b) second parameters for experimenting on the second design stage.

Example 35 includes the apparatus of example 34, wherein to generate the adjusted parameters for experimenting on the class of design stages, the slice rearrangement circuitry is to adjust (a) the first parameters of the first design stage and (b) the second parameters of the second design stage based on the group of operations.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. An apparatus to group design stages in design space optimization of semiconductor design, the apparatus comprising:
interface circuitry;
first instructions; and
processor circuitry to at least one of instantiate or execute the first instructions to:
parse a file to identify a first design stage of a design flow and a second design stage of the design flow, the first design stage and the second design stage corresponding to a class of design stages;
generate, based on a dictionary file, a group of operations to perform the first design stage and the second design stage, the dictionary file associated with the first design stage and the second design stage;
generate adjusted parameters for experimenting on the class of design stages, the adjusted parameters based on the group of operations; and
generate second instructions based on the group of operations and the adjusted parameters.

2. The apparatus of claim 1, wherein the processor circuitry is to determine the dictionary file associated with the first design stage and the second design stage.

3. The apparatus of claim 2, wherein to determine the dictionary file, the processor circuitry is to identify (a) a first variable of the first design stage on which to experiment and (b) a second variable of the second design stage on which to experiment.

4. The apparatus of claim 2, wherein to determine the dictionary file, the processor circuitry is to identify (a) a first operation of the first design stage and (b) a second operation of the second design stage.

5. The apparatus of claim 4, wherein to generate the group of operations, the processor circuitry is to adjust (a) the first operation of the first design stage and (b) the second operation of the second design stage.

6. The apparatus of claim 2, wherein to determine the dictionary file, the processor circuitry is to identify (a) first parameters for experimenting on the first design stage and (b) second parameters for experimenting on the second design stage.

7. The apparatus of claim 6, wherein to generate the adjusted parameters for experimenting on the class of design stages, the processor circuitry is to adjust (a) the first parameters of the first design stage and (b) the second parameters of the second design stage based on the group of operations.

8. A non-transitory machine-readable storage medium comprising first instructions that, when executed, cause processor circuitry to at least:
parse a file to identify a first design stage of a design flow and a second design stage of the design flow, the first design stage and the second design stage corresponding to a class of design stages;
generate, based on a dictionary file, a group of operations to perform the first design stage and the second design stage, the dictionary file associated with the first design stage and the second design stage;
generate adjusted parameters for experimenting on the class of design stages, the adjusted parameters based on the group of operations; and
generate second instructions based on the group of operations and the adjusted parameters.

9. The non-transitory machine-readable storage medium of claim 8, wherein the first instructions cause the processor circuitry to determine the dictionary file associated with the first design stage and the second design stage.

10. The non-transitory machine-readable storage medium of claim 9, wherein to determine the dictionary file, the first instructions cause the processor circuitry to identify (a) a first variable of the first design stage on which to experiment and (b) a second variable of the second design stage on which to experiment.

11. The non-transitory machine-readable storage medium of claim 9, wherein to determine the dictionary file, the first instructions cause the processor circuitry to identify (a) a first operation of the first design stage and (b) a second operation of the second design stage.

12. The non-transitory machine-readable storage medium of claim 11, wherein to generate the group of operations, the first instructions cause the processor circuitry to adjust (a) the first operation of the first design stage and (b) the second operation of the second design stage.

13. The non-transitory machine-readable storage medium of claim 9, wherein to determine the dictionary file, the first instructions cause the processor circuitry to identify (a) first parameters for experimenting on the first design stage and (b) second parameters for experimenting on the second design stage.

14. The non-transitory machine-readable storage medium of claim 13, wherein to generate the adjusted parameters for experimenting on the class of design stages, the first instructions cause the processor circuitry to adjust (a) the first parameters of the first design stage and (b) the second parameters of the second design stage based on the group of operations.

15. A method to group design stages in design space optimization of semiconductor design, the method comprising:
parsing a file to identify a first design stage of a design flow and a second design stage of the design flow, the first design stage and the second design stage corresponding to a class of design stages;
based on a dictionary file, generating, by executing a first instruction with processor circuitry, a group of operations to perform the first design stage and the second design stage, the dictionary file associated with the first design stage and the second design stage;
generating, by executing a first instruction with the processor circuitry, adjusted parameters for experimenting on the class of design stages, the adjusted parameters based on the group of operations; and
generating, by executing a first instruction with the processor circuitry, second instructions based on the group of operations and the adjusted parameters.

16. The method of claim 15, further including determining the dictionary file associated with the first design stage and the second design stage.

17. The method of claim 16, wherein determining the dictionary file includes identifying (a) a first variable of the first design stage on which to experiment and (b) a second variable of the second design stage on which to experiment.

18. The method of claim 16, wherein determining the dictionary file includes identifying (a) a first operation of the first design stage and (b) a second operation of the second design stage.

19. The method of claim 18, wherein generating the group of operations includes adjusting (a) the first operation of the first design stage and (b) the second operation of the second design stage.

20. The method of claim 16, wherein determining the dictionary file includes identifying (a) first parameters for experimenting on the first design stage and (b) second parameters for experimenting on the second design stage.

21.-35. (canceled)
